(19) United States
(12) Patent Application Publication
(10) Pub. No.: US 2010/0080255 A1
(43) Pub. Date: Apr. 1, 2010

(54) SEMICONDUCTOR LASER DEVICE

(75) Inventor: Akiyoshi SUGAHARA, Osaka-shi (JP)

Correspondence Address: MORRISON & FOERSTER LLP, 1650 TYSONS BOULEVARD, SUITE 400, MCLEAN, VA, 22102, US

(73) Assignee: Sharp Kabushiki Kaisha, Osaka-shi (JP)

(21) Appl. No.: 12/564,552

(22) Filed: Sep. 22, 2009

(30) Foreign Application Priority Data
Sep. 29, 2008 (JP) 2008-250462

(51) Int. Cl. H01S 5/323; H01S 5/00

(52) U.S. Cl. 372/45.01

(57) ABSTRACT

A resonator in a semiconductor laser device includes a semiconductor substrate, an n-type cladding layer and a p-type cladding layer formed on or above the semiconductor substrate, and an active layer sandwiched between the n-type cladding layer and the p-type cladding layer. A ridge extending in an axial direction of the resonator is formed at an upper surface of the resonator. The ridge includes an emitting-side end portion, a non-emitting-side end portion, a taper portion allowing a width of the ridge to be decreased in a taper-like manner from the emitting-side end portion toward the non-emitting-side end portion, and a step portion provided on a side of the emitting-side end portion with respect to the non-emitting-side end portion, and allowing the width of the ridge to be changed in a step-like manner.

This nonprovisional application is based on Japanese Patent Application No. 2008-250462 filed on Sep. 29, 2008, with the Japan Patent Office, the entire contents of which are hereby incorporated by reference.

### BACKGROUND OF THE INVENTION

1. Field of the Invention

The present invention relates to a semiconductor laser device, and particularly relates to a semiconductor laser device used for an optical pickup device and others.

2. Description of the Background Art

In recent years, a recording speed has been improved in an optical pickup device. For example, a CD-R, a DVD-R/RW, and others that have achieved a 16× recording speed have been commercialized. To increase the recording speed, the semiconductor laser device is required to achieve high power.

To allow the semiconductor laser device to achieve high power, there is a demand for: a high COD (Catastrophic Optical Damage) level, namely, a high optical power limitation determined by a COD; linearity in current-optical power characteristics, namely, a high kink level; and a low operating current in a high-temperature operation, and others.

To improve the COD level, as shown in Japanese Patent Laying-Open No. 2001-015864, for example, a so-called “laser with facet window” is employed, which has an emitting facet with no optical absorption properties. In the “laser with facet window”, zinc (Zn) or the like is thermally diffused to thereby disorder an active layer in a quantum well structure and increase a band gap, so that optical absorption at the emitting facet is prohibited, and that breakage of the facet that would be caused by temperature rise resulted from the optical absorption is suppressed. Furthermore, a facet window portion is structured such that no current flows therethrough.

To increase the kink level, a width of a stripe that serves as a waveguide is generally decreased. If a stripe width is large, optical confinement in a lateral direction becomes unstable, resulting in a kink. Generally, the width of a stripe is adjusted in a range from approximately 1 μm to 5 μm. On the other hand, to reduce electric power consumption, there is a demand for maximizing a stripe width so as to lower an operating voltage. As described above, it is necessary to adjust the stripe width such that occurrence of a kink can be suppressed and that electric power consumption can be reduced.

Furthermore, a taper structure allowing the stripe width to be gradually changed in a resonator has conventionally been used as well. Such a taper structure is shown in, for example, Japanese Patent Laying-Open No. 2000-312053, Japanese Patent Laying-Open No. 2002-280668, a pamphlet of International Publication No. 2005/062433, and others.

One advantage of the gradual change in stripe width in a resonator is that an operating voltage can be lowered while occurrence of a kink is suppressed. The reason why an operating voltage can be lowered is that an increase in area of the stripe, namely, an increase in area of a current path causes a decrease in series resistance.

The increase in area of the current path causes an increase in current required for laser oscillation, and inevitably causes an increase in oscillation threshold value. However, by appropriately selecting a shape of the taper and an area of the stripe, the increase in oscillation threshold value can be outweighed by the advantage of a decrease in operating voltage, and as a whole, electric power consumption can be reduced.

Further in the above-described taper structure, an increase in area of the stripe causes a decrease in current density. Therefore, the taper structure is more suitable for a high-temperature operation.

Moreover, a large stripe width causes a decrease in influences of stress received from an electrode metal or the like, and a decrease in irregularities of a far-field pattern, so that the far-field pattern further approaches a Gaussian distribution. Therefore, when the taper structure is employed, the side having a larger stripe width is set to serve as an emitting side.

Additionally, by increasing a stripe width of the emitting facet, an optical density at the facet is decreased and temperature rise is suppressed, so that a temperature difference becomes smaller between at the time of low power output and at the time of high power output. As a result, changes in refractive index distribution are reduced, producing an effect of reducing a change between the half-value width of a far-field pattern at the time of low power output and the half-value width of a far-field pattern at the time of high power output.

An example of a conventional high-power semiconductor laser device will be described with reference to FIG. 15.

FIG. 15 shows an AlGaInP-based facet window structure. This semiconductor laser device has a structure of stacked layers successively formed above an n-type GaAs substrate 51. This stacked-layer structure includes at least an n-type AlGaInP cladding layer 52, a multiple quantum well active layer 53 including a non-doped AlGaInP optical guide layer, a non-doped GaInP well layer, and a non-doped AlGaInP barrier layer, a p-type AlGaInP cladding layer 54, a p-type GaInP discontinuous band relaxing layer 55, and a p-type GaAs cap layer 56. At a part of p-type AlGaInP cladding layer 54, p-type GaInP discontinuous band relaxing layer 55, and p-type GaAs cap layer 56, a stripe-like ridge having a prescribed width is formed. Further, in proximity to a facet of the resonator, a window portion is formed in which zinc (Zn) is diffused to thereby disorder the quantum well layer. Further, a portion other than the window portion located in proximity to the facet (hereinafter this portion is sometimes referred to as an “internal portion” or an “internal region”) is covered with an insulating film 57 except for a portion on the ridge, and an electrode (not shown) for ohmic contact is formed only at P-type GaAs cap layer 56 on the ridge in the internal portion. A current flows only through the ridge portion in the internal portion, whereas no current is injected into the window portion.

Regarding the shape of the stripe at this time, there are a case that the stripe width is constant in the resonator (FIG. 16), a case that the stripe width is gradually changed in a part of the resonator (FIG. 17), a case that the stripe width is gradually changed in the entire resonator (FIG. 18), and other cases.

In the case that the stripe width is constant in the resonator as in FIG. 16, it is necessary to adjust the stripe width so as to suppress occurrence of a kink. The operating voltage at that time becomes inevitably higher when compared with the operating voltage of the taper structures as shown in FIGS. 17 and 18 (see the graph in FIG. 19).

To implement a high-temperature and high-power operation, low electric power consumption is required, and thus the taper structure is more suitable.

In the case of the conventional taper structures as in FIGS. 17 and 18, however, various disadvantages occur in a manufacturing process.

As shown in FIG. 20, to link the stripes contiguously in the manufacturing process, for example, a stripe pattern is formed and split into bars, and then multilayer dielectric films having different reflectances are formed at an emitting surface and a non-emitting surface, respectively.

At this time, the side having a larger stripe width is set as an emitting surface side. As shown in FIG. 20, however, the emitting surface sides are not oriented to the same direction, and hence a step of forming a multilayer dielectric film becomes burdensome.

In the case of using a misoriented substrate as shown in FIG. 21, facets having two types of shapes are fabricated, so that in assembly, the steps become burdensome because of adjustment of a position of a luminous point, and others.

To overcome these disadvantages, as shown in FIG. 22, it may be possible to employ a structure that allows the stripe width to be gradually increased toward the non-emitting side.

In this case, when the stripe shape is optimized to reduce electric power consumption, it is necessary to decrease the stripe width on the emitting side in exchange for the increase in area of the stripe on the non-emitting side, to thereby control the total area of the stripe.

If the stripe width on the emitting side is decreased, the effect of reducing irregularities of the far-field pattern, and the effect of decreasing dependency of a half-value width on power are decreased. In other words, this case further approaches the case of a constant stripe width, resulting in a loss of the effect of the taper structure.

### SUMMARY OF THE INVENTION

An object of the present invention is to provide a semiconductor laser device capable of implementing a high-temperature and high-power operation, while suppressing complications in manufacturing steps.

A semiconductor laser device according to the present invention is a semiconductor laser device including a resonator having an emitting-side end portion, a non-emitting-side end portion, and an upper surface. The resonator includes a semiconductor substrate, an n-type cladding layer and a p-type cladding layer formed on or above the semiconductor substrate, and an active layer sandwiched between the n-type cladding layer and the p-type cladding layer. A protruding portion extending in an axial direction of the resonator is formed at the upper surface of the resonator. The protruding portion includes a first end portion positioned at the emitting-side end portion, a second end portion positioned at the non-emitting-side end portion and having the same width as a width of the first end portion, a taper portion allowing a width of the protruding portion to be decreased in a taper-like manner from the first end portion toward the second end portion, and a step portion provided on a side of the first end portion with respect to the second end portion, and allowing the width of the protruding portion to be changed in a step-like manner.

In one aspect, in the semiconductor laser device described above, a no-current-injection region is provided at each of the emitting-side end portion and the non-emitting-side end portion in the resonator.

In one aspect, in the semiconductor laser device described above, the step portion in the protruding portion is formed in the no-current-injection region provided at the non-emitting-side end portion.

In one aspect, in the semiconductor laser device described above, in the no-current-injection region provided at the emitting-side end portion, the first end portion in the protruding portion has a portion having a constant width, and the step portion in the protruding portion is formed in the no-current-injection region provided at the non-emitting-side end portion.

In one aspect, in the semiconductor laser device described above, in at least a part of the no-current-injection region provided at each of the emitting-side end portion and the non-emitting-side end portion, the active layer is allowed to have a portion formed to have a band gap larger than a band gap of a portion of the resonator interposed between the no-current-injection regions.

In one aspect, in the semiconductor laser device described above, a minimum value of the width of the protruding portion is equal to or more than 0.5 μm and equal to or less than 3.0 μm.

In one aspect, in the semiconductor laser device described above, a maximum value of the width of the protruding portion is 1.2 times or more and 3.0 times or less a minimum value of the width of the protruding portion.

In one aspect, in the semiconductor laser device described above, a no-current-injection region is provided at at least the non-emitting-side end portion in the resonator, and a length of the taper portion is 0.2 times or more a length of the resonator, and is equal to or less than a length obtained by subtracting, from the length of the resonator, a length of the no-current-injection region provided at the non-emitting-side end portion.

In one aspect, in the semiconductor laser device described above, the active layer includes one of GaInP and AlGaInP.

In one aspect, in the semiconductor laser device described above, the active layer includes one of GaAs and AlGaAs.

In one aspect, in the semiconductor laser device described above, the active layer includes one of GaN and InGaN.

In one aspect, the semiconductor laser device described above oscillates at two or more different wavelengths.

According to the present invention, it is possible to achieve a high-temperature and high-power operation of the semiconductor laser device, while suppressing complications in the steps of manufacturing the semiconductor laser device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram showing a shape of a stripe in a resonator in a semiconductor laser device according to first to fourth embodiments of the present invention.

FIG. 2 is a schematic diagram showing a cross section of the semiconductor laser device according to the first embodiment of the present invention, in proximity to a facet (no-current-injection portion).

FIG. 3 is a schematic diagram showing a cross section of an internal portion of the semiconductor laser device according to the first embodiment of the present invention.

FIGS. 4-11 are diagrams each showing comparison of properties between an example of the semiconductor laser device according to the first embodiment of the present invention and a conventional semiconductor laser device.

FIGS. 12A and 12B are schematic diagrams each showing a cross section of a semiconductor laser device according to a second embodiment of the present invention. FIG. 12A shows a cross section of an internal portion, while FIG. 12B shows a cross section of the semiconductor laser device in proximity to a facet (no-current-injection portion).

FIGS. 13A and 13B are schematic diagrams each showing a cross section of a semiconductor laser device according to a third embodiment of the present invention. FIG. 13A shows a cross section of an internal portion, while FIG. 13B shows a cross section of the semiconductor laser device in proximity to a facet (no-current-injection portion).

FIGS. 14A and 14B are schematic diagrams each showing a cross section of a semiconductor laser device according to a fourth embodiment of the present invention. FIG. 14A shows a cross section of an internal portion, while FIG. 14B shows a cross section of the semiconductor laser device in proximity to a facet (no-current-injection portion).

FIG. 15 is a perspective view showing an example of a conventional semiconductor laser device.

FIG. 16 is a diagram showing an example of a stripe shape in the conventional semiconductor laser device.

FIG. 17 is a diagram showing another example of a stripe shape in the conventional semiconductor laser device.

FIG. 18 is a diagram showing still another example of a stripe shape in the conventional semiconductor laser device.

FIG. 19 is a diagram showing an operating voltage of the conventional semiconductor laser devices.

FIG. 20 is a diagram for describing a state of being split into bars in the conventional semiconductor laser device.

FIG. 21 is a diagram for describing a chip shape and a position of a luminous point in the conventional semiconductor laser device.

FIG. 22 is a diagram showing a further example of a stripe shape in the conventional semiconductor laser device.

### DESCRIPTION OF THE PREFERRED EMBODIMENTS

Embodiments of the present invention will hereinafter be described. It is noted that the same or corresponding portions are provided with the same reference characters and the description thereof may not be repeated.

It is also noted that, if the number, amount, and others are referred to in the embodiments described below, the scope of the present invention is not necessarily limited to the number, amount and others unless otherwise specified. Further, each component in the embodiments below is not necessarily essential to the present invention unless otherwise specified. Further, if a plurality of embodiments are provided in the following, it is intended from the beginning to combine as appropriate the configurations of the embodiments unless otherwise specified.

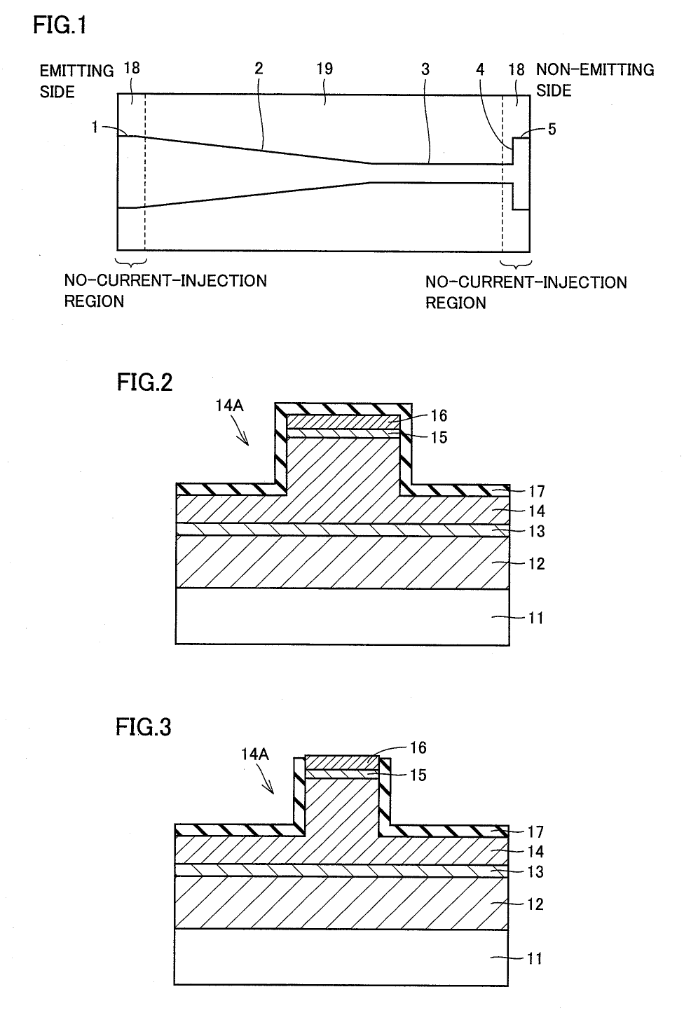

FIG. 1 is a schematic diagram showing a shape of a stripe in a resonator in a semiconductor laser device according to first to fourth embodiments described below. With reference to FIG. 1, the shape of a stripe in the semiconductor laser device according to the first to fourth embodiments described below includes an emitting-side end portion 1, a taper portion 2, a small-width portion 3, a step portion 4, and a non-emitting-side end portion 5.

Emitting-side end portion 1 and non-emitting-side end portion 5 are formed to have approximately the same width. Taper portion 2 is formed to have a width decreasing from the emitting side toward the non-emitting side. Small-width portion 3 is positioned on the non-emitting side with respect to taper portion 2. Small-width portion 3 has a constant width. Step portion 4 is positioned between small-width portion 3 and non-emitting-side end portion 5, and serves for changing the stripe width in a stepwise manner (step-like manner). Advantages of employing such a stripe shape will be described later.

It is noted that a window region 18, which is identified as a no-current-injection region, is provided at each of opposite ends of the resonator. Between the window regions, an internal region 19 is provided. Step portion 4 is formed in window region 18 provided on the non-emitting side. Further, emitting-side end portion 1 has a portion with a constant width in window region 18 provided on the non-emitting side.

### First Embodiment

FIG. 2 is a cross-sectional view showing a cross section of window region 18 in the semiconductor laser device according to the first embodiment of the present invention. FIG. 3 is a cross-sectional view showing a cross section of internal region 19 in the semiconductor laser device.

As shown in FIGS. 2 and 3, the semiconductor laser device according to the present embodiment has a structure of stacked layers successively formed above an n-type GaAs substrate 11, the stacked-layer structure at least including: an n-type AlGaInP cladding layer 12; a multiple quantum well active layer 13 including a non-doped AlGaInP optical guide layer, a non-doped GaInP well layer, and a non-doped AlGaInP barrier layer; a p-type AlGaInP cladding layer 14; a p-type GaInP discontinuous band relaxing layer 15; and a p-type GaAs cap layer 16. In window region 18 (FIG. 2) provided in proximity to a facet of the resonator, zinc (Zn) is diffused to thereby disorder multiple quantum well active layer 13. The length of window region 18 is, for example, approximately 30 μm. A part of p-type AlGaInP cladding layer 14, p-type GaInP discontinuous band relaxing layer 15, and p-type GaAs cap layer 16 form a stripe-like ridge 14A.

In internal region 19 as shown in FIG. 3, a location other than an upper surface portion of the ridge is covered with an insulating film 17 made of silicon oxide, silicon nitride, or the like, and an electrode (not shown) for ohmic contact is formed thereon to thereby allow a current to flow only through ridge 14A.

On the other hand, in window region 18 as shown in FIG. 2, insulating film 17 is formed even on ridge 14A, so that no current is injected thereinto.

In at least a part of window region 18, multiple quantum well active layer 13 is allowed to have a portion formed to have a band gap larger than a band gap of internal region 19. Thereby, optical absorption at the facet of the resonator is eliminated, so that the facet is prevented from being broken by the temperature rise that would be caused by the optical absorption.

As shown in FIG. 1, the stripe shape has taper portion 2 that allows a stripe width to be gradually changed in a part of the resonator.

In the present embodiment, the resonator has a length of 1500 μm, the smallest stripe width is 1.5 μm, the largest stripe width, which is on the emitting surface side, is 3.0 μm, and the length of taper portion 2 is 1000 μm.

Further, emitting-side end portion 1 positioned at an end portion of window region 18, which is identified as a no-current-injection region, has a stripe width of 3.0 μm. On the non-emitting surface side, the stripe width is changed from 1.5 μm to 3.0 μm in a stepwise manner in window region 18, which is identified as a no-current-injection region.

Window region 18 is a no-current-injection region located in proximity to the facet, and thus even if the stripe width is drastically changed in a stepwise manner as described above, properties cannot be influenced thereby.

In the case that the stripe width is made constant in the resonator, occurrence of a kink can be suppressed by adjusting the stripe width to approximately 1.5 μm. However, the semiconductor laser device according to the present embodiment produces the effects as described below, in contrast to the conventional semiconductor laser having a constant stripe width of 1.5 μm.

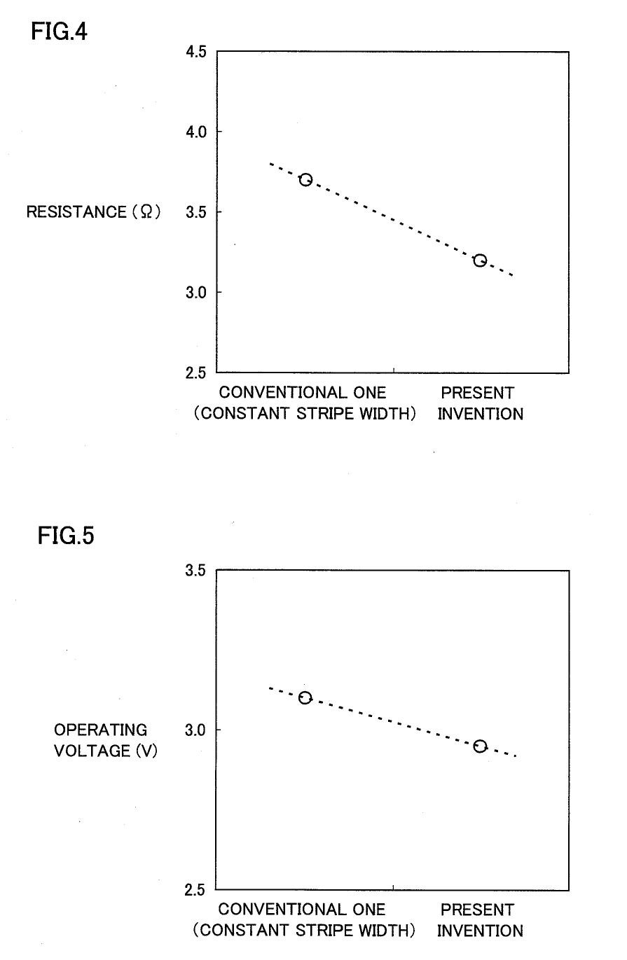

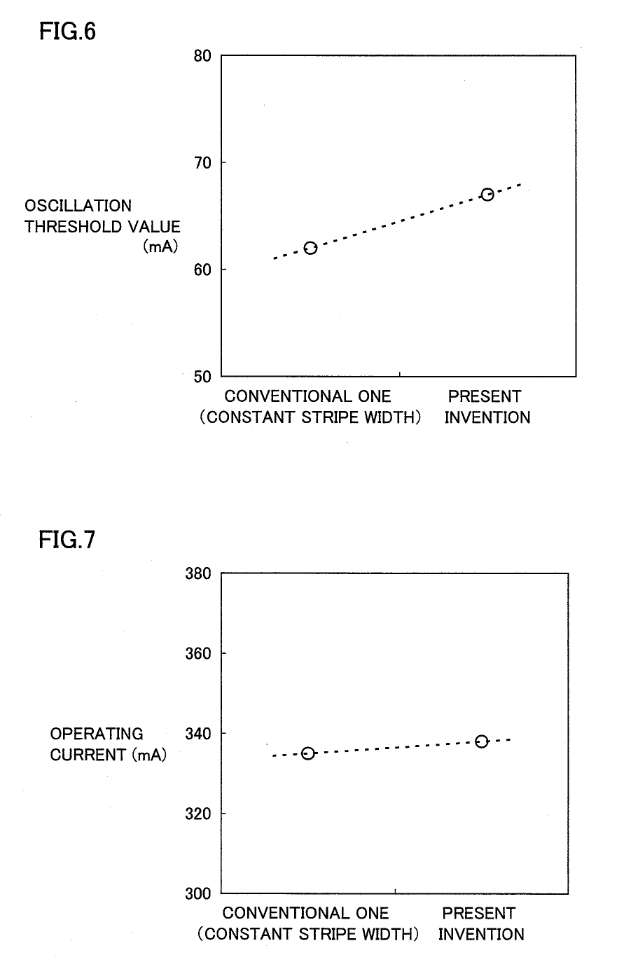

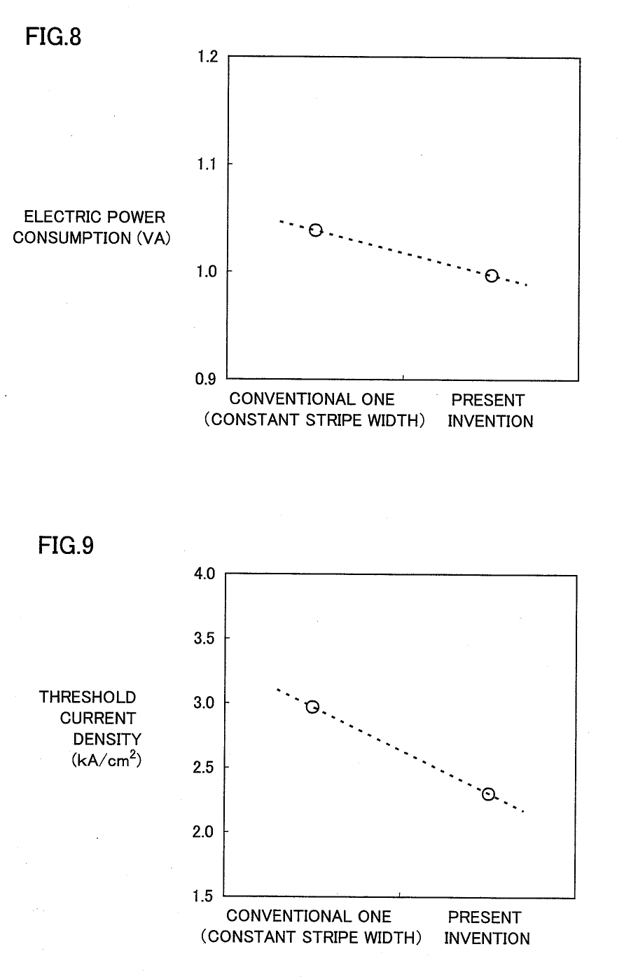

In other words, comparison is made between the properties of the conventional semiconductor laser device (represented in FIGS. 4-11 as “CONVENTIONAL ONE (CONSTANT STRIPE WIDTH)” and the properties of the semiconductor laser device having the taper stripe structure according to the present embodiment (represented in FIGS. 4-11 as “PRESENT INVENTION”). In the semiconductor laser device according to the present embodiment, (a) resistance is decreased (FIG. 4), and (b) an operating voltage at the time of high-power oscillation is decreased (FIG. 5). Furthermore, (c) although an oscillation threshold value is increased (FIG. 6), (d) an operating current at the time of high-power oscillation remains almost unchanged (FIG. 7). As a result, (e) electric power consumption (a product of the operating current and the operating voltage) is decreased (FIG. 8).

The reason why the operating current at the time of high-power oscillation remains almost unchanged although the oscillation threshold value is increased, as described above, is considered to be that (f) the threshold current density is decreased (FIG. 9), so that a temperature characteristic is improved and an increase in operating current is suppressed.

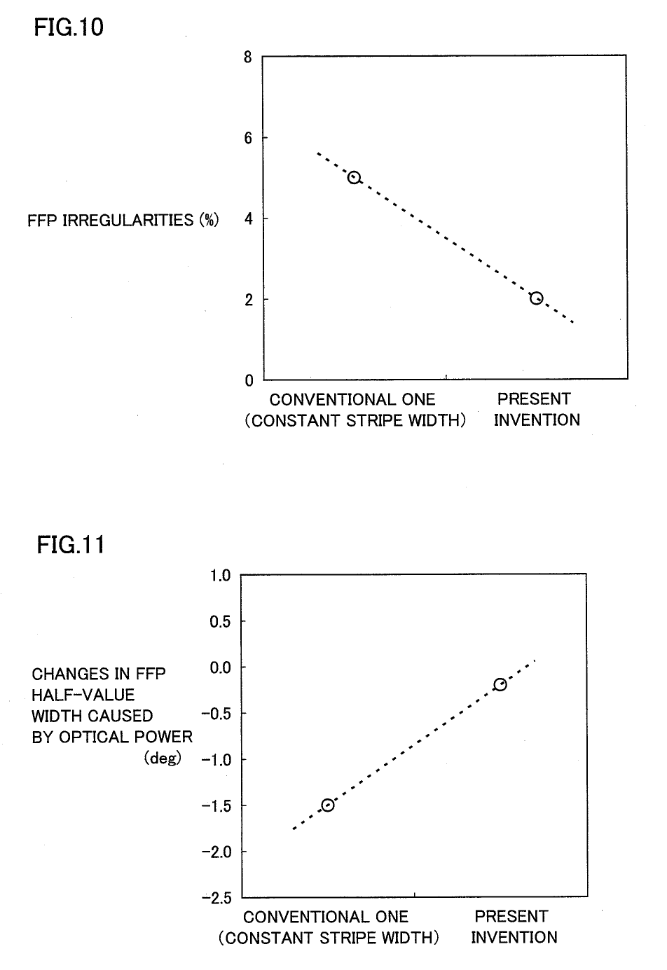

Furthermore, (g) irregularities of the far-field pattern (FFP) in a horizontal direction is decreased (FIG. 10), and (h) changes in half-value width of the far-field pattern in a horizontal direction, caused by an optical power, are reduced as well (FIG. 11).

Here, the irregularities of the far-field pattern are defined by a ratio of deviation from a Gaussian curve, and the changes in half-value width of the far-field pattern in a horizontal direction, caused by an optical power, are defined by a difference between a half-value width of the far-field pattern during write and a half-value width of the far-field pattern during read.

Further in the present embodiment, the emitting surface side and the non-emitting surface side have the same stripe width, and hence the semiconductor laser device according to the present embodiment is similar to the conventional one having a constant stripe width, from a viewpoint of manufacturing steps, and thus can easily be fabricated.

Here, the smallest stripe width equal to or less than 0.5 μm causes difficulties in manufacturing, and hence is not practical. In contrast, the relevant width exceeding 3 μm makes the transverse mode unstable, resulting in that a kink is more likely to occur. Further preferably, the relevant width equal to or less than 2 μm can further suppress a kink.

In the present embodiment, the largest stripe width (W2) is twice as large as the smallest stripe width (W1). If the largest stripe width is 1.2 times or less the smallest stripe width, the effect of improving properties by forming the taper-shaped stripe is decreased. Conversely, if the largest stripe width is more than 3 times the smallest stripe width, irregularities of the far-field pattern are reduced and the far-field pattern becomes more stable. However, an area of the stripe becomes excessively large, so that an increase in operating current is more significant than a decrease in operating voltage, resulting in that electric power consumption ceases to decrease. Further preferably, by setting W2 to be approximately 2 times W1, it is possible to achieve both of stability in far-field pattern and reduction in electric power consumption.

In the present embodiment, taper portion 2 has a length of 1000 μm, which is 0.67 times the resonator length. If the length of taper portion 2 is less than 0.2 times the resonator length, the effect of reducing electric power consumption owing to an increase in area is suppressed. Preferably, by setting the length of taper portion 2 to be 0.4 times or more the resonator length, large effects can be obtained. On the non-emitting surface side, the stripe width is changed in a stepwise manner in window region 18, which is identified as a no-current-injection region. Taper portion 2 may extend up to the portion where the stripe width is changed in a stepwise manner. Preferably, the length of taper portion 2 is 0.8 times or less the resonator length.

Furthermore, by providing a portion having a constant stripe width on each of the emitting surface side and the non-emitting surface side, it is possible to ensure the likelihood of successful division at a split position when a bar is split from a wafer, so that productivity is improved.

The above-described features will be summarized as follows. Specifically, the semiconductor laser device according to the present embodiment includes a resonator 100. Resonator 100 includes: n-type GaAs substrate 11 serving as a “semiconductor substrate”; n-type AlGaInP cladding layer 12 serving as an “n-type cladding layer” and p-type AlGaInP cladding layer 14 serving as a “p-type cladding layer”, formed on or above n-type GaAs substrate 11; and multiple quantum well active layer 13 serving as an “active layer” sandwiched between n-type AlGaInP cladding layer 12 and p-type AlGaInP cladding layer 14. Ridge 14A serving as a “protruding portion” extending in an axial direction of the resonator is formed at an upper surface of the resonator. Ridge 14A includes emitting-side end portion 1 serving as a “first end portion”, non-emitting-side end portion 5 serving as a “second end portion” having the same width as a width of emitting-side end portion 1, taper portion 2 allowing a width of ridge 14A to be decreased in a taper-like manner from emitting-side end portion 1 toward non-emitting-side end portion 5, and step portion 4 serving as a “step portion” provided on a side of emitting-side end portion 1 with respect to non-emitting-side end portion 5, and allowing the width of ridge 14A to be changed in a step-like manner.

In the semiconductor laser device according to the present embodiment, the stripe width on the non-emitting side is changed in a stepwise manner in the no-current-injection region so as to match the stripe width on the non-emitting side with the stripe width on the emitting side in the taper stripe structure. By doing so, it is possible to reduce electric power consumption and improve far-field pattern characteristics, while suppressing complications in manufacturing steps. As a result, it is possible to achieve a high-power semiconductor laser device required for a record-type optical pickup.

### Second Embodiment

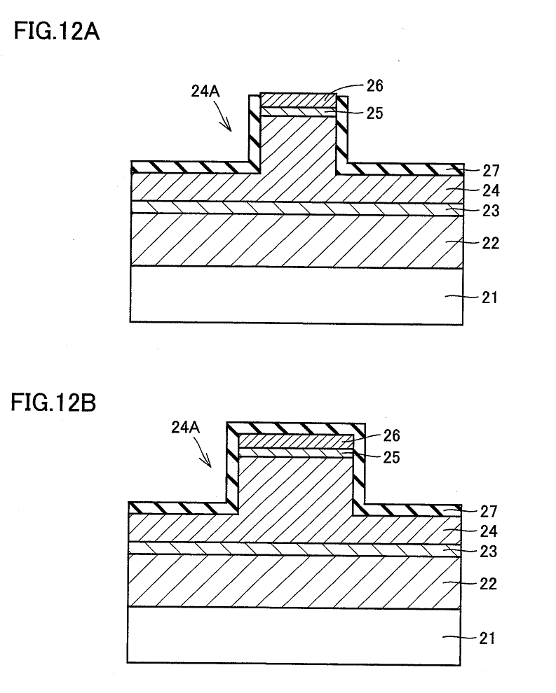

FIGS. 12A and 12B are schematic diagrams each showing a cross section of a semiconductor laser device according to a second embodiment. FIG. 12A shows a cross section of internal region 19, while FIG. 12B shows a cross section of window region 18.

The semiconductor laser device is a modification of the semiconductor laser device according to the first embodiment, characterized in that the multiple quantum well active layer includes GaAs and AlGaAs, and that the semiconductor laser device is a high-power infrared laser device for a CD-R, having an oscillation wavelength in a 780 nm band.

With reference to FIGS. 12A and 12B, the semiconductor laser device according to the present embodiment has a structure of stacked layers successively formed above an n-type GaAs substrate 21. The stacked-layer structure is made of at least an n-type AlGaInP cladding layer 22, a multiple quantum well active layer 23 including a non-doped AlGaAs optical guide layer, a non-doped GaAs well layer, and a non-doped AlGaAs barrier layer, a p-type AlGaInP cladding layer 24, a p-type GaInP discontinuous band relaxing layer 25, and a p-type GaAs cap layer 26. In proximity to a facet of the resonator, there is formed window region 18 having a length of approximately 30 μm, in which zinc (Zn) is diffused to thereby disorder multiple quantum well active layer 23. A stripe-like ridge 24A is formed at a part of p-type AlGaInP cladding layer 24, p-type GaInP discontinuous band relaxing layer 25, and p-type GaAs cap layer 26.

In internal region 19, the location other than an upper surface portion of the ridge is covered with an insulating film 27 made of silicon oxide, silicon nitride, or the like. An electrode (not shown) for ohmic contact is formed thereon, so as to allow a current to flow only through ridge 24A (FIG. 12A).

In window region 18, the insulating film is formed even on the ridge, so that no current is injected thereinto (FIG. 12B).

It is noted that the stripe shape has taper portion 2 that allows the stripe width to be gradually changed in a part of the resonator, as shown in FIG. 1.

Further, the resonator length is 1000 μm, the smallest stripe width (W1) is 2 μm, the largest stripe width (W2) is 4 μm, the length of the taper region is 600 μm, the length of window region 18, into which no current is injected, is 30 μm on the emitting side and 30 μm on the non-emitting surface side.

Emitting-side end portion 1 positioned at an end portion of window region 18, which is identified as a no-current-injection region, has a stripe width of 4.0 μm. On the non-emitting surface side, the stripe width is changed in a stepwise manner from 4.0 μm to 2.0 μm in window region 18, which is identified as a no-current-injection region.

In the semiconductor laser device according to the present embodiment as well, it is possible to obtain effects similar to those of the semiconductor laser device according to the first embodiment.

### Third Embodiment

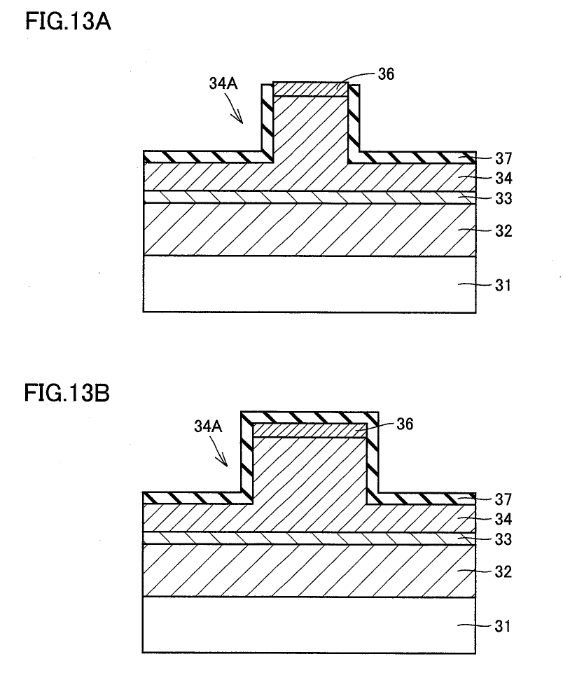

FIGS. 13A and 13B are schematic diagrams each showing a cross section of a semiconductor laser device according to a third embodiment. FIG. 13A shows a cross section of internal region 19, while FIG. 13B shows a cross section of window region 18.

This semiconductor laser device is a modification of the semiconductor laser devices according to the first and second embodiments, characterized in that the structure of the multiple quantum well active layer includes GaN and InGaN, and that the semiconductor laser device is a high-power infrared laser device for a BD, having an oscillation wavelength in a 405 nm band.

With reference to FIGS. 13A and 13B, the semiconductor laser device according to the present embodiment has a structure of stacked layers successively formed above an n-type GaN substrate 31. The stacked-layer structure is made of at least an n-type AlGaN cladding layer 32, a multiple quantum well active layer 33 including a GaN optical guide layer, an InGaN well layer, and a barrier layer made of GaN and InGaN, a p-type AlGaN cladding layer 34, and a p-type GaN contact layer 36. In proximity to a facet of the resonator, window region 18 having a length of approximately 30 μm is formed. A stripe-like ridge 34A is formed at a part of p-type AlGaN cladding layer 34 and p-type GaN contact layer 36.

In internal region 19, a location other than an upper surface portion of the ridge is covered with an insulating film 37 made of silicon oxide, silicon nitride, or the like. An electrode (not shown) for ohmic contact is formed thereon, so as to allow a current to flow only through ridge 34A (FIG. 13A).

In window region 18, the insulating film is formed even on the ridge, so that no current is injected thereinto (FIG. 13B).

It is noted that the stripe shape has taper portion 2 that allows the stripe width to be gradually changed in a part of the resonator, as shown in FIG. 1.

The resonator length is 800 μm, the smallest stripe width (W1) is 2 μm, the largest stripe width (W2) is 4 μm, the length of the taper region is 500 μm, the length of window region 18, into which no current is injected, is 30 μm on the emitting side and 30 μm on the non-emitting surface side.

Further, emitting-side end portion 1 positioned at an end portion of window region 18, which is identified as a no-current-injection region, has a stripe width of 2.0 μm. On the non-emitting surface side, the stripe width is changed in a stepwise manner from 4.0 μm to 2.0 μm in window region 18, which is identified as a no-current-injection region.

In the semiconductor laser device according to the present embodiment as well, it is possible to obtain effects similar to those of the semiconductor laser devices according to the first and second embodiments.

### Forth Embodiment

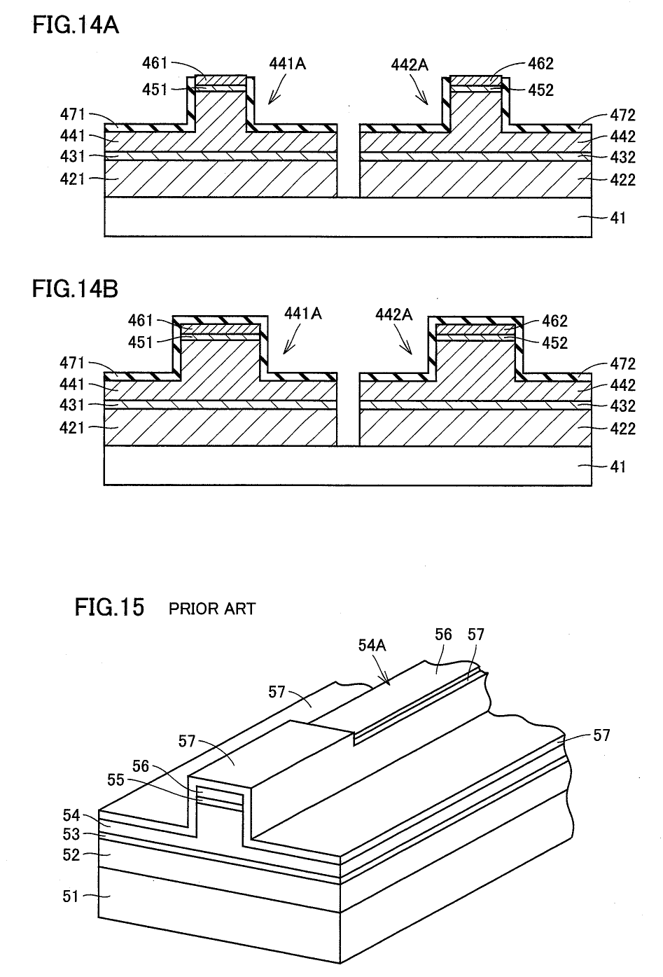

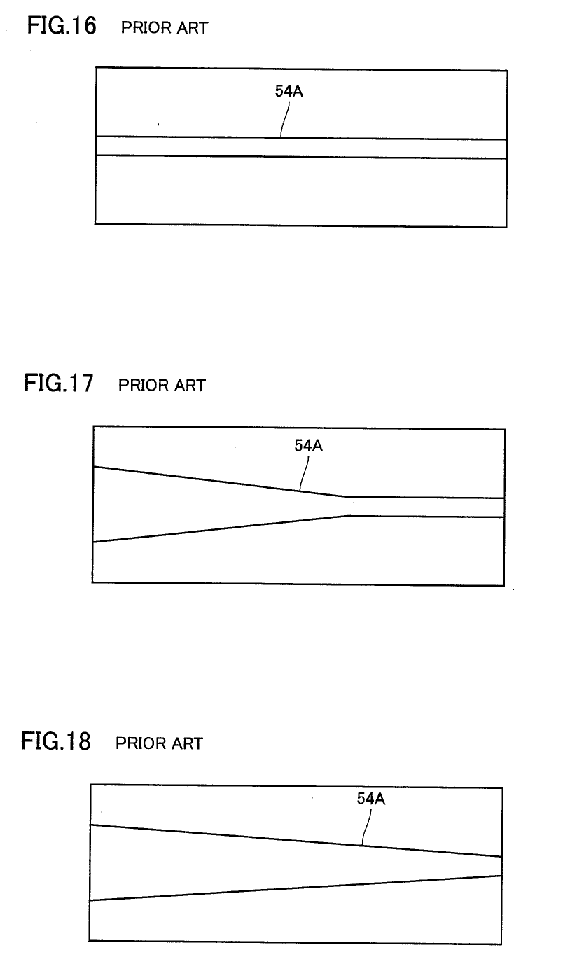

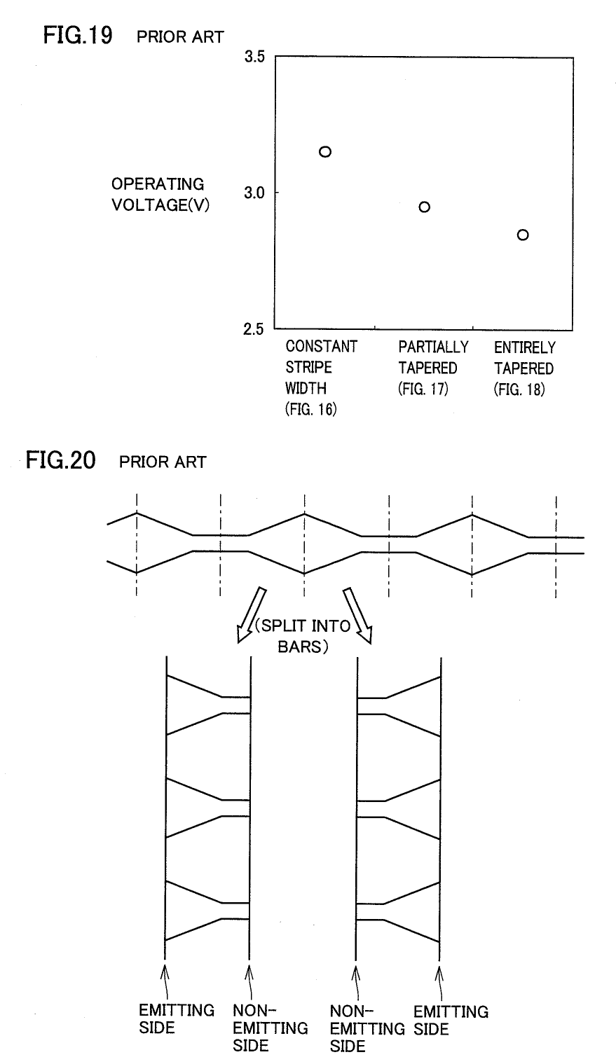

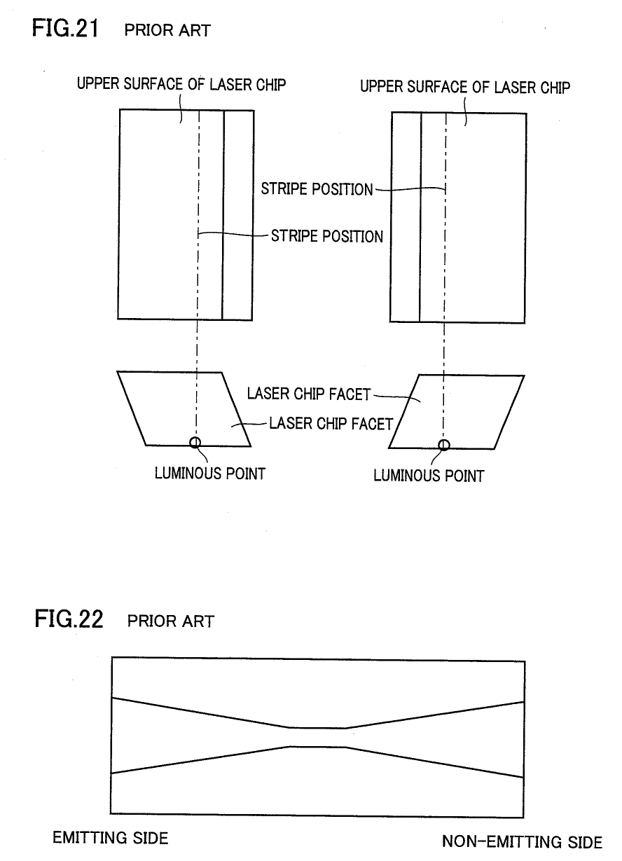

FIGS. 14A and 14B are schematic diagrams each showing a cross section of a semiconductor laser device according to a fourth embodiment. FIG. 14A shows a cross section of internal region 19, while FIG. 14B shows a cross section of window region 18.

This semiconductor laser device is a modification of the semiconductor laser devices according to the first to third embodiments, and is a monolithic semiconductor laser device in which two semiconductor laser devices are mounted on a single chip. One characteristic thereof is that the semiconductor laser device includes two semiconductor laser devices, namely, a first semiconductor laser device which has a multiple quantum well active layer including GaAs and AlGaAs and oscillates in a 780 nm band, and a second semiconductor laser device which has a multiple quantum well active layer including GaInP and oscillates in a 660 nm band. In other words, the semiconductor laser device according to the present embodiment oscillates at two or more different wavelengths.

With reference to FIGS. 14A and 14B, in the semiconductor laser device according to the present embodiment, the first semiconductor laser device has a structure of stacked layers successively formed above an n-type GaAs substrate 41. The stacked-layer structure is made of at least an n-type AlGaInP cladding layer 421, a multiple quantum well active layer 431 including a non-doped AlGaInP optical guide layer, a non-doped GaInP well layer, and a non-doped AlGaInP barrier layer, a p-type AlGaInP cladding layer 441, a p-type GaInP discontinuous band relaxing layer 451, and a p-type GaAs cap layer 461. In proximity to a facet of the resonator, window region 18 having a length of approximately 30 μm is formed. A stripe-like ridge 441A is formed at a part of p-type AlGaInP cladding layer 441, p-type GaInP discontinuous band relaxing layer 451, and p-type GaAs cap layer 461.

In the semiconductor laser device according to the present embodiment, the second semiconductor laser device has a structure of stacked layers successively formed above n-type GaAs substrate 41. The stacked-layer structure is made of at least an n-type AlGaInP cladding layer 422, a multiple quantum well active layer 432 including a non-doped AlGaAs optical guide layer, a non-doped GaAs well layer, and a non-doped AlGaAs barrier layer, a p-type AlGaInP cladding layer 442, a p-type GaInP discontinuous band relaxing layer 452, and a p-type GaAs cap layer 462. In proximity to a facet of the resonator, window region 18 having a length of approximately 30 μm is formed. A stripe-like ridge 442A is formed at a part of p-type AlGaInP cladding layer 442, p-type GaInP discontinuous band relaxing layer 452, and p-type GaAs cap layer 462.

In internal regions 19 in the first and second semiconductor laser devices, locations other than upper surface portions of the ridges are covered with insulating films 471, 472 made of silicon oxide, silicon nitride, or the like, respectively. Electrodes (not shown) for ohmic contact are formed thereon, so as to allow a current to flow only through ridges 441A, 442A (FIG. 14A).

In window region 18 in each of the first and second semiconductor laser devices, an insulating film is formed even on the ridge, so that no current is injected thereinto (FIG. 14B).

It is noted that in each of the first and second semiconductor laser devices, the stripe shape includes taper portion 2 that allows the stripe width to be gradually changed in a part of the resonator as shown in FIG. 1.

The resonator length of the semiconductor laser device according to the present embodiment is 1500 μm.

In the first semiconductor laser device, the smallest stripe width (W1) is 2 μm, the largest stripe width (W2) is 4 μm, the length of the taper region is 1000 μm, and the length of window region 18, into which no current is injected, is 30 μm on the emitting side and 30 μm on the non-emitting surface side. Further, emitting-side end portion 1 positioned at an end portion of window region 18, which is identified as a no-current-injection region, has a stripe width of 4.0 μm. On the non-emitting surface side, the stripe width is changed in a stepwise manner from 4.0 μm to 2.0 μm in window region 18, which is identified as a no-current-injection region.

In addition, in the second semiconductor laser device, the smallest stripe width (W1) is 1.5 μm, the largest stripe width (W2) is 3 μm, the length of the taper region is 1000 μm, the length of window region 18, into which no current is injected, is 30 μm on the emitting side and 30 μm on the non-emitting surface side. Further, emitting-side end portion 1 positioned at an end portion of window region 18, which is identified as a no-current-injection region, has a stripe width of 3.0 μm. On the non-emitting surface side, the stripe width is changed in a stepwise manner from 3.0 μm to 1.5 μm in window region 18, which is identified as a no-current-injection region.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor laser device, comprising a resonator having an emitting-side end portion, a non-emitting-side end portion, and an upper surface,
said resonator including
a semiconductor substrate,
an n-type cladding layer and a p-type cladding layer formed on or above said semiconductor substrate, and
an active layer sandwiched between said n-type cladding layer and said p-type cladding layer,
a protruding portion extending in an axial direction of said resonator being formed at said upper surface of said resonator, and
said protruding portion including
a first end portion positioned at said emitting-side end portion,
a second end portion positioned at said non-emitting-side end portion and having the same width as a width of said first end portion,
a taper portion allowing a width of said protruding portion to be decreased in a taper-like manner from said first end portion toward said second end portion, and
a step portion provided on a side of said first end portion with respect to said second end portion, and allowing the width of said protruding portion to be changed in a step-like manner.

2. The semiconductor laser device according to claim 1, wherein a no-current-injection region is provided at each of said emitting-side end portion and said non-emitting-side end portion in said resonator.

3. The semiconductor laser device according to claim 2, wherein said step portion in said protruding portion is formed in said no-current-injection region provided at said non-emitting-side end portion.

4. The semiconductor laser device according to claim 3, wherein in at least a part of said no-current-injection region provided at each of said emitting-side end portion and said non-emitting-side end portion, said active layer is allowed to have a portion formed to have a band gap larger than a band gap of a portion of the resonator interposed between the no-current-injection regions.

5. The semiconductor laser device according to claim 2, wherein
in said no-current-injection region provided at said emitting-side end portion, said first end portion in said protruding portion has a portion having a constant width, and
said step portion in said protruding portion is formed in said no-current-injection region provided at said non-emitting-side end portion.

6. The semiconductor laser device according to claim 1, wherein a minimum value of the width of said protruding portion is equal to or more than 0.5 μm and equal to or less than 3.0 μm.

7. The semiconductor laser device according to claim 1, wherein a maximum value of the width of said protruding portion is 1.2 times or more and 3.0 times or less a minimum value of the width of said protruding portion.

8. The semiconductor laser device according to claim 1, wherein
a no-current-injection region is provided at at least said non-emitting-side end portion in said resonator, and
a length of said taper portion is 0.2 times or more a length of said resonator, and is equal to or less than a length obtained by subtracting, from the length of said resonator, a length of said no-current-injection region provided at said non-emitting-side end portion.

9. The semiconductor laser device according to claim 1, wherein said active layer includes one of GaInP and AlGaInP.

10. The semiconductor laser device according to claim 1, wherein said active layer includes one of GaAs and AlGaAs.

11. The semiconductor laser device according to claim 1, wherein said active layer includes one of GaN and InGaN.

12. The semiconductor laser device according to claim 1, oscillating at two or more different wavelengths.
